(19) United States
(12) Patent Application Publication
(10) Pub. No.: US 2026/0238127 A1
(43) Pub. Date: Aug. 13, 2026

(54) MULTIPHASE POWER CONVERTER

(71) Applicant: Renesas Electronics America Inc., Milpitas, CA (US)

(72) Inventor: Benoit LABBE, Harlow (GB)

(73) Assignee: Renesas Electronics America Inc., Milpitas, CA (US)

(21) Appl. No.: 19/049,249

(22) Filed: Feb. 10, 2025

(51) Int. Cl. H02M 3/158; H02M 1/00; H02M 1/32; H02M 3/00

(52) U.S. Cl. CPC H02M 3/158; H02M 1/0009; H02M 1/0025; H02M 1/32; H02M 3/003

(57) ABSTRACT

A multiphase power converter is provided. The multiphase power converter includes a plurality of phases, a coupling inductor, and a sensing circuit. Each phase comprises a pair of power switches coupled to a transformer. The coupling inductor is coupled to a transformer of a chosen phase among the plurality of phases. The sensing circuit generates a first parameter related to a current through the coupling inductor.

### TECHNICAL FIELD

The present disclosure relates to a multiphase power converter, and in particular to a transformer-based multiphase power converter.

### BACKGROUND

Multiphase power converters are used for various types of applications.

The transient performances of multiphase converters can be improved with a use of coupled inductors (i.e. transformers). Such circuits can be referred to as Transformer based Voltage Regulator (TLVR).

The inductor current sensing methods used in multiphase power converters are often complex and or expensive to implement.

It is an object of the disclosure to address one or more of the above mentioned limitations.

### SUMMARY

According to a first aspect of the disclosure there is provided a multiphase power converter comprising a plurality of phases wherein each phase comprises a pair of power switches coupled to a transformer; a coupling inductor coupled to a transformer of a chosen phase among the plurality of phases; and a sensing circuit adapted to generate a first parameter related to a current through the coupling inductor.

Optionally, the sensing circuit is adapted to generate a second parameter related to an approximate value of a total current provided by the plurality of phases, and a third parameter based on the first parameter and the second parameter; wherein the third parameter is related to the total current.

Optionally, each transformer is formed of a primary winding and a secondary winding; wherein the primary windings are coupled to an output port, and wherein the secondary windings are coupled to each other in series; wherein the coupling inductor is coupled to the secondary winding of the chosen phase.

Optionally, the sensing circuit comprises a DC resistance circuit for providing the first parameter, wherein the DC resistance circuit comprises a resistor and a first capacitor, and wherein the first parameter is a voltage across the first capacitor.

Optionally, the sensing circuit comprises a shunt circuit for providing the first parameter.

Optionally, wherein the sensing circuit comprises a hall-effect circuit for providing the first parameter.

Optionally, the sensing circuit comprises for each phase a resistance coupled between a switching node of the phase and a common node common to all phases.

Optionally, the multiphase power converter comprises a second capacitor coupled between the common node and the output port.

For instance, the second parameter may be a voltage across the second capacitor.

Optionally, the sensing circuit comprises a first transconductance amplifier configured to receive the first parameter, a second transconductance coupled to the common node, and a summation resistance coupled to both outputs of the first and second transconductance amplifiers; and wherein the third parameter is a voltage across the summation resistance.

Optionally, the sensing circuit comprises a first electronic amplifier coupled to a first filter, and a second electronic amplifier coupled to a second filter.

For instance, the first electronic amplifier and the second electronic amplifier may be implemented as current conveyor circuits (CCIs).

Optionally, the first electronic amplifier has a first input coupled to a first terminal of the coupling inductor and a second input coupled to a second terminal of the coupling inductor, and wherein the second electronic amplifier has a first input coupled to an output node and a second input coupled to the common node.

Optionally, the sensing circuit comprises a differential amplifier having a first input coupled to the first filter and a second input coupled to the second filter, and an output for providing the third parameter.

Optionally, the multiphase power converter comprises a plurality of drivers for driving the plurality of phases and a controller configured to control the plurality of drivers, wherein the controller is configured to receive the third parameter in a feedback loop.

Optionally, the chosen phase is a first phase or a last phase among the plurality of phases.

According to a second aspect of the disclosure there is provided a method of operating a multiphase power converter in which each phase comprises a pair of power switches coupled to a transformer, the method comprising
providing a coupling inductor coupled to a transformer of a chosen phase among the plurality of phases; and
generating with a sensing circuit a first parameter related to a current through the coupling inductor.

Optionally, the method further comprises
generating with the sensing circuit a second parameter related to an approximate value of a total current provided by the plurality of phases of the multiphase power converter;
generating with the sensing circuit a third parameter based on the first parameter and the second parameter; and
estimating the total current using the third parameter.

### DESCRIPTION OF THE DRAWINGS

The disclosure is described in further detail below by way of example and with reference to the accompanying drawings, in which:

FIG. 1A is a diagram of a four-phases buck power converter according to the prior art;

FIG. 1B is a diagram of a four-phases buck converter provided with DCR sensing at each phase according to the prior art;

FIG. 2 is a diagram of a four-phases buck converter provided with global DCR sensing;

FIG. 3 is a diagram of a conventional transformer based voltage regulator (TLVR);

FIG. 4 is a flow chart of a method for operating a multiphase power converter in which each phase comprises a pair of power switches coupled to a transformer;

FIG. 5 is a diagram of a multiphase power converter according to the disclosure;

FIG. 6A is a diagram of a hall-effect circuit;

FIG. 6B is a diagram of a shunt circuit;

FIG. 7 is a diagram of a modified version of the multiphase power converter of FIG. 5;

FIG. 8A is a diagram showing an RC-gm structure;

FIG. 8B is a diagram showing a gm-RC structure;

FIG. 9 is an exemplary implementation of an amplification stage for use in FIG. 8B;

FIG. 10 is a diagram of another multiphase power converter according to the disclosure;

FIG. 11A is a simulation of a TLVR converter having 16 phases with DCR observer for the total primary current and the coupling inductor current;

FIG. 11B is a detailed view of the rising load transient section of FIG. 11A; and

FIG. 11C is a detailed view of the harmonic load test section of FIG. 11A.

### DESCRIPTION

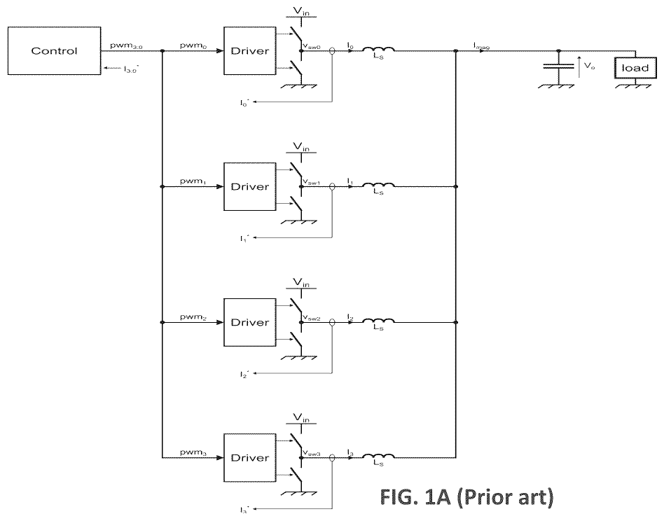

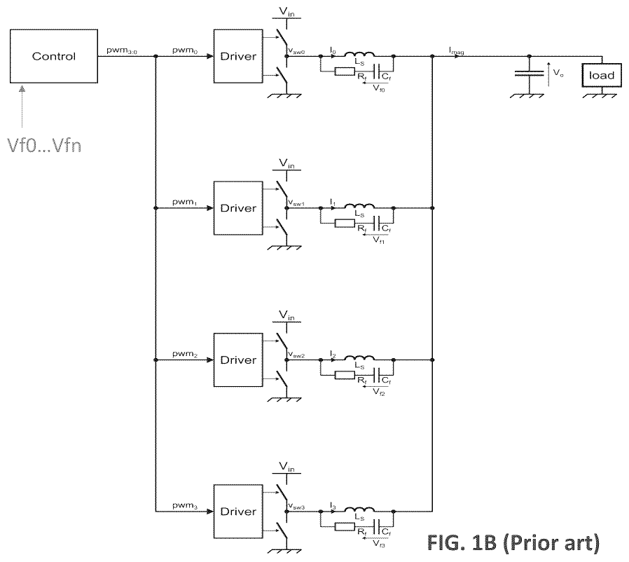

FIG. 1A is a diagram of a four-phases buck power converter according to the prior art. In this circuit the phase currents I0, I1, I2 and I3 are sensed and fed-back to the control circuit. Sensing the current delivered by the inductors to the load and output decoupling capacitor permits delivering good transient performances.

The phase currents may be sensed by measuring the voltage drop across the active power switches and replicating it. However, for cost sensitive applications DCR sensing solution may be preferred.

FIG. 1B is a diagram of a four-phases buck converter provided with DCR sensing at each phase according to the prior art. A RC network in parallel with the inductor acts as an observer for the inductor current. The voltage V_{fn} across the capacitors Cf mimics the inductor current Iₙ in which n is the phase under consideration and each inductor L has a DC resistance characteristic R₁.

Setting the observer values for Rf and Cf appears when writing the branch equations between switching nodes and output voltage in the Laplace domain for phase n:

$${V}_{swn} - {V}_{o} = ( {R}_{f} {C}_{f} s + 1 ) {V}_{fn} = ( L s + {R}_{l} ) {I}_{n}$$

Rearranging terms yields:

$${V}_{fn} = {R}_{l} \frac{\frac{L}{{R}_{l}} s + 1}{{R}_{f} {C}_{f} s + 1} {I}_{n}$$

In which “s” is the Laplace complex variable.

By setting the time constant of the observer equal to the inductor time constant one can reconstruct the inductor current information as the voltage across the observer capacitor:

$${V}_{fn} \approx {R}_{l} {I}_{n}$$

While this solution is simple and can be effective it requires many inputs for the controller circuit if the observer network is external to the controller integrated circuit. Furthermore, knowing each phase current independently may not be needed for controlling the converter and only knowledge of the total current delivered by the magnetic components, I_{mag}, is sufficient.

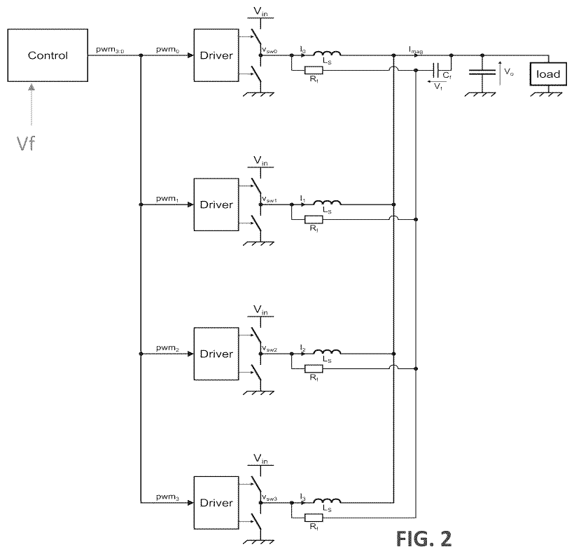

FIG. 2 is a diagram of a four-phases buck converter provided with global DCR sensing.

The global current observer method observes the magnetic components current, I_{mag}, while reducing the number of passive components and interconnects required by the observer.

Deriving the global current observer equations follows the same method as for a single-phase observer. Considering a converter with N phases:

$$- {NV}_{o} + {\sum }_{i = 0}^{N - 1} {V}_{{sw}_{i}} = ( {sR}_{f} {C}_{f} + N ) {V}_{f} = ( Ls + {R}_{l} ) {I}_{mag}$$

Rearranging terms yields the global observer equation:

$${V}_{f} = \frac{{R}_{l}}{N} \times \frac{\frac{L}{{R}_{l}} s + 1}{\frac{{R}_{f} {C}_{f}}{N} s + 1} {I}_{mag}$$

By setting the RC time constant of the observer appropriately, the pole of the transfer function can cancel its zero and the global observer equation becomes:

$${V}_{f} \approx \frac{{R}_{l}}{N} {I}_{mag}$$

The transient performances of multiphase buck converters can be improved with a use of coupled inductors (i.e. transformers).

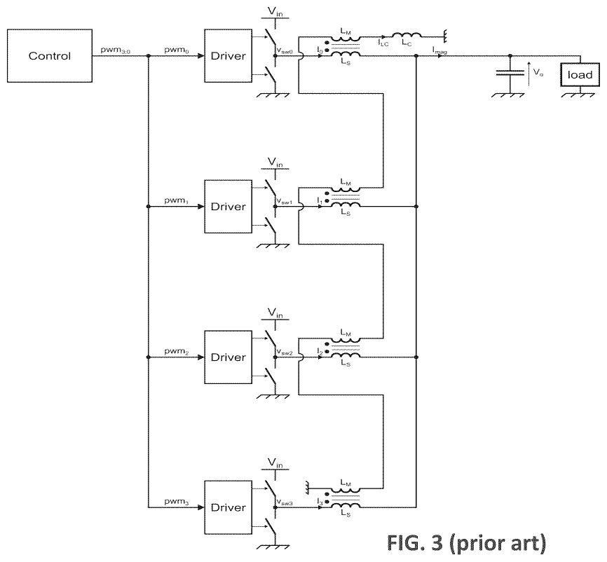

FIG. 3 is a diagram of a conventional transformer based voltage regulator (TLVR).

In this topology all inductors of the 4 phases buck converter are replaced by the primary inductance of a transformer and its secondary is serially connected to the other phase secondaries. A coupling inductor Lc loads the secondaries (L_{M}) of the transformers. The coupling inductor L_{C} has a DC parasitic resistance, R_{LC}, and carries a current ILC.

The following equation is obtained for each primary inductor current Iₙ:

$${L}_{S} \frac{{dI}_{n}}{dt} + {L}_{M} \frac{{dI}_{L C}}{dt} = - {R}_{L} {I}_{n} + {V}_{{sw}_{n}} - {V}_{o}$$

The magnetic coupling requires extensive matrix calculation to describe the system with a set of first order differential equations. The total magnetic current, I_{mag}, still follows the Kirchoff laws and is at least one time derivative:

$${I}_{mag} = {\sum }_{i = 0}^{N - 1} {I}_{i}$$

$$Thus :$$

$${L}_{S} {\sum }_{i = 0}^{N - 1} \frac{{dI}_{i}}{dt} + {L}_{M} N \frac{{dI}_{LC}}{dt} = - {R}_{L} {\sum }_{i = 0}^{N - 1} {I}_{i} + {\sum }_{i = 0}^{N - 1} {V}_{{sw}_{i}} - {NV}_{o}$$

Simplifying and rearranging terms yields:

$${L}_{S} \frac{{dI}_{mag}}{dt} + {R}_{L} {I}_{mag} + {L}_{M} N \frac{{dI}_{LC}}{dt} = - {NV}_{o} + {\sum }_{i = 0}^{N - 1} {v}_{{sw}_{i}}$$

This equation shows that while the average steady-state current through the coupling inductor L_{C} is negligible, its transient part is not and the term:

$$\frac{{dI}_{LC}}{dt}$$

cannot be ignored for proper current reconstruction.

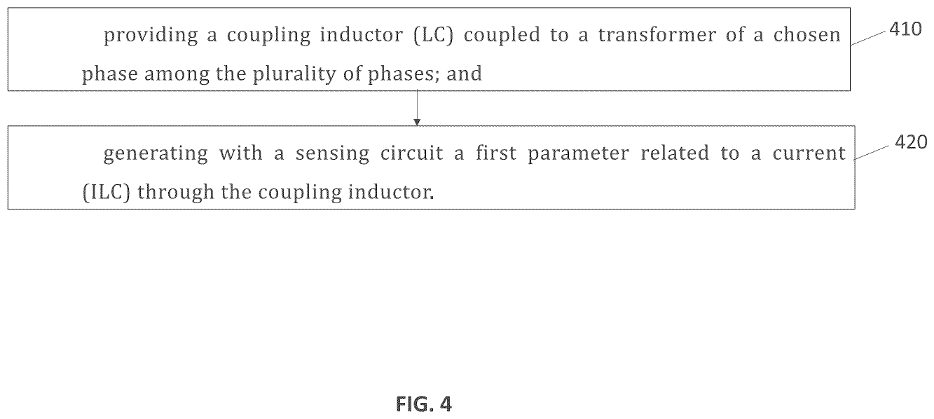

FIG. 4 is a flow chart of a method of operating a multiphase power converter in which each phase comprises a pair of power switches coupled to a transformer.

At step 410 a coupling inductor (L_{C}) coupled to a transformer of a chosen phase among the plurality of phases is provided. For instance, the chosen phase may be a first phase or a last phase among the plurality of phases.

At step 420 a first parameter related to a current (I_{LC}) through the coupling inductor is generated with a sensing circuit.

The method may further include additional steps.

For instance the sensing circuit may be used to generate a second parameter related to an approximate value of a total current (I_{mag}) provided by the plurality of phases of the multiphase power converter. Then a third parameter can be generated based on the first parameter and the second parameter. The third parameter can then be used to estimate the total current (I_{mag}).

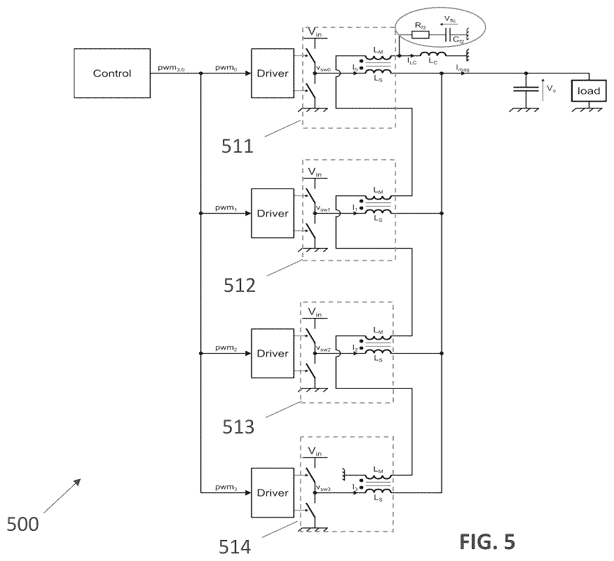

FIG. 5 is a diagram of a multiphase power converter according to the disclosure. The multiphase power converter 500 includes a plurality of phases. In this example four phases are provided 511-514. Phase 511 is referred to as the first phase and phase 514 is referred to as the last phase in the series of phases. Each phase comprises a pair of power switches coupled to a transformer.

Each transformer is formed of a primary winding (L_{S}) and a secondary winding (L_{M}). The primary windings are coupled to an output port, and the secondary windings are coupled to each other in series.

A coupling inductor (L_{C}) is coupled to the transformer of the first phase 511. Alternatively, the coupling inductor could be coupled to the transformer of the last phase 514. The coupling inductor (L_{C}) is coupled to the secondary winding (L_{M}) of the first phase 511.

The converter 500 further includes a sensing circuit to generate a first parameter related to a current (I_{LC}) through the coupling inductor. In this example the sensing circuit comprises a DC resistance (DCR) circuit for providing the first parameter. The DCR circuit is formed of a resistor (R_{f2}) and a first capacitor (C_{f2}). The first parameter is a voltage (V_{f1c}) across the first capacitor (C_{f2}).

The multiphase power converter 500 also includes a four of drivers for driving the four phases. A controller is provided to control the drivers.

The first parameter or another parameter based on the first parameter may be sent back to the controller as a feedback parameter.

The simplest approach for observing the current through the coupling inductor is to use DCR sensing as shown in the present example. However, the DCR circuit could be replaced with a shunt circuit or with a hall-effect circuit.

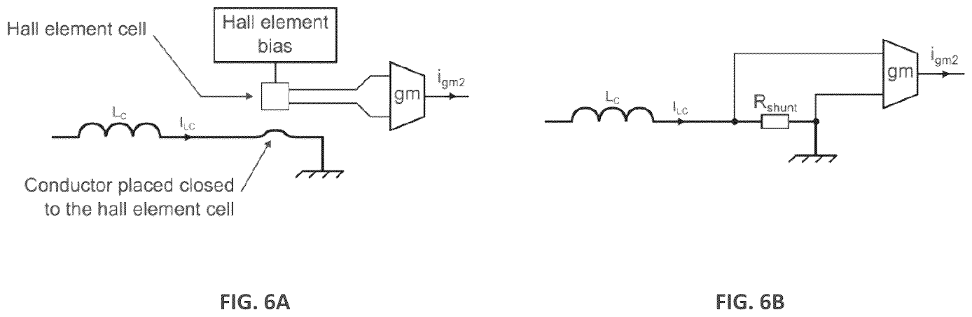

FIG. 6A is a diagram of a hall-effect circuit. The hall-effect circuit includes a conductor placed in close proximity to a hall element, and a transconductance amplifier coupled to the Hall element. The hall-effect circuit can be used to sense the first parameter.

FIG. 6B is a diagram of a shunt circuit. The shunt circuit includes a shunt resistor coupled to Lc and a transconductance amplifier coupled to the shunt resistor. The shunt circuit can be used to sense the first parameter.

Following from the circuit of FIG. 2 provided with global DCR, rewriting the global observer equation in the Laplace domain for the TLVR topology yields:

$$( {L}_{S} s + {R}_{L} ) {I}_{mag} + {L}_{M} {NsI}_{LC} = {\sum }_{i = 0}^{N - 1} {V}_{{sw}_{i}} - {NV}_{o} = ( {sR}_{f} {C}_{f} + N ) {V}_{f}$$

And rearranging terms gives:

$${I}_{mag} = \frac{{sR}_{f} {C}_{f} + N}{{L}_{S} s + {R}_{L}} {V}_{f} - \frac{{L}_{M} Ns}{{L}_{S} s + {R}_{L}} {I}_{LC}$$

Introducing R_{f2} and C_{f2} in the equation system:

$${I}_{mag} = \frac{N}{{R}_{L}} \times \frac{\frac{{R}_{f} {C}_{f}}{N} s + 1}{\frac{{L}_{S}}{{R}_{L}} s + 1} {V}_{f} - \frac{N}{{R}_{L}} \times \frac{{L}_{M} s}{\frac{{L}_{S}}{{R}_{L}} s + 1} \times \frac{1}{{R}_{LC}} \times \frac{1 + {R}_{flc} {C}_{flc} s}{1 + \frac{{L}_{LC}}{{R}_{LC}} s} {G}_{LC} {V}_{flc}$$

The secondary current observer can be tuned to balance the inductance zero and the RC pole:

$${I}_{mag} = \frac{N}{{R}_{L}} [ \frac{\frac{{R}_{f} {C}_{f}}{N} s + 1}{\frac{{L}_{S}}{{R}_{L}} s + 1} {V}_{f} - \frac{\frac{{L}_{M}}{{R}_{LC}} s}{\frac{{L}_{S}}{{R}_{L}} s + 1} {V}_{flc} ]$$

It is now apparent that by measuring two voltages and balancing time constants one can estimate the total magnetic current delivered to the load-side of the TLVR.

$$By setting :$$

$$\frac{{R}_{F} {C}_{F}}{N} \approx \frac{{L}_{S}}{{R}_{L}}$$

$$one can obtain :$$

$${I}_{mag} = \frac{N}{{R}_{L}} [ {V}_{f} - \frac{\frac{{L}_{M}}{{R}_{LC}} s}{\frac{{L}_{S}}{{R}_{L}} s + 1} {V}_{flc} ]$$

The TLVR operation of the converter of FIG. 5 relies on AC coupling of the coupling inductor. One can assume that the frequency content of the current through the coupling inductor is above the corner frequency of the low pass filter:

$$H ( s ) = \frac{\frac{{L}_{M}}{{R}_{LC}} s}{\frac{{L}_{S}}{{R}_{L}} s + 1}$$

This leads to the simplification of the observer equation:

$${I}_{mag} \approx \frac{N}{{R}_{L}} [ {V}_{f} - \frac{{L}_{M} {R}_{L}}{{L}_{S} {R}_{LC}} {V}_{flc} ]$$

Measuring a difference between V_{f} and V_{f1c} is not generally sufficient to obtain an observation of the primary magnetic current I_{mag} and a gain must be introduced.

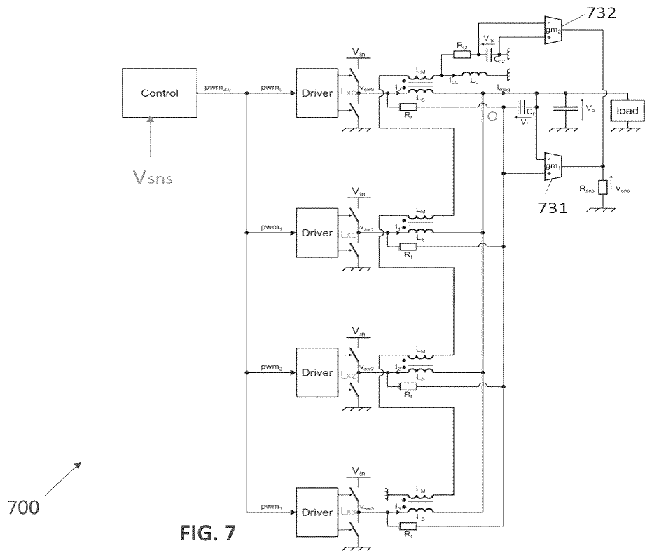

FIG. 7 is a diagram of a modified version of the multiphase power converter of FIG. 5. The circuit 700 is similar to the circuit 500, but in this example the sensing circuit is adapted to generate a second parameter (V_{f}) related to an approximate value of a total current (I_{mag}) provided by the plurality of phases, and a third parameter (Vₛₙₛ) based on the first parameter and the second parameter; wherein the third parameter is related to the total current (I_{mag}).

The sensing circuit comprises for each phase a resistance (R_{f}) coupled between a switching node Lx of the phase and a common node O, common to all phases. In addition a second capacitor (C_{f}) is coupled between the common node O and the output port of the converter.

The sensing circuit includes two transconductance amplifiers 731, 732. The transconductance amplifier 732 is configured to receive the first parameter.

In this example 732 has a first input coupled to a first terminal of C_{f2}, and a second input coupled to a second terminal of C_{f2}.

The transconductance amplifier 731 has a first input coupled to a first terminal of C_{f}, and a second input coupled to a second terminal of C_{f} at the common node O. A summation resistance (Rₛₙₛ) is coupled to both outputs of the transconductance amplifiers 731 and 732. The voltage (Vₛₙₛ) across the summation resistance (Rₛₙₛ) provides the third parameter.

In operation the voltages across the capacitors C_{f} and C_{f2} are sensed with the two transconductance amplifiers 731 and 732, with gains gm₁ and gm₂, whose outputs drive the summation resistance Rₛₙₛ. The voltage Vₛₙₛ across the summation resistance (Rₛₙₛ) mimic the global magnetic current I_{mag}.

$${V}_{sns} can be expressed as : \\ {V}_{sns} = {R}_{sns} ( {gm}_{1} {V}_{f} - {gm}_{2} {V}_{flc} )$$

$$Rearranging terms : \\ {V}_{sns} = {R}_{sns} {gm}_{1} ( {V}_{f} - \frac{{gm}_{2}}{{gm}_{1}} {V}_{flc} )$$

$$Setting : \\ \frac{{gm}_{2}}{{gm}_{1}} = \frac{{L}_{M} {R}_{L}}{{L}_{S} {R}_{LC}}$$

$$Gives : \\ \frac{{V}_{sns}}{{R}_{sns} {gm}_{1}} = {V}_{f} - \frac{{L}_{M} {R}_{L}}{{L}_{S} {R}_{L C}} {V}_{flc} = \frac{{I}_{mag} {R}_{L}}{N}$$

Which yields a functioning global current observer:

$${V}_{sns} = {I}_{mag} \frac{{R}_{L} {R}_{sns} g {m}_{1}}{N}$$

The sensing circuit may be implemented in different ways. For instance the sensing circuit may have a filter stage followed by an amplification stage or the other way round an amplification stage followed by a filter stage.

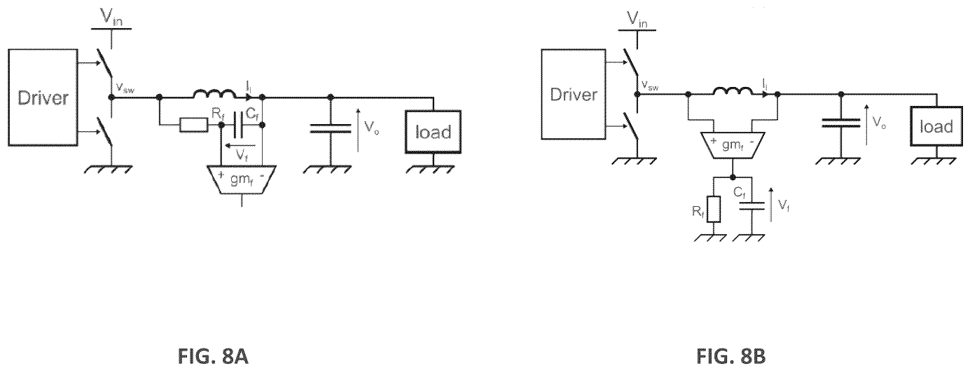

FIG. 8A is a diagram showing an RC-gm structure. The RC filter is connected to the inductor and the transconductance amplifier is connected across the capacitor. In applications where sensing the voltage across the observer capacitor is difficult, a gm-RC structure can be employed.

FIG. is a diagram showing a gm-RC structure. The transconductance amplifier is connected across the inductor and the RC filter is coupled to the output of the transconductance amplifier. The inductor branch equation has not changed, and can be expressed as:

$${V}_{sw} - {V}_{o} = ( sL + {R}_{L} ) {I}_{l}$$

The observer voltage V_{f} can be expressed as:

$${V}_{f} = \frac{{R}_{f}}{1 + {R}_{f} {C}_{f} s} {gm}_{f} ( {V}_{sw} - {V}_{o} ) \\ {V}_{f} = {R}_{f} {gm}_{f} {R}_{L} \times \frac{1 + \frac{L}{{R}_{L}} s}{1 + {R}_{f} {C}_{f} s} {I}_{l}$$

Which has the same form as the RC observer with a different gain tuning. Equalising the time constants and setting the gm-R gain to 1 yield:

$${V}_{f} \approx {R}_{L} {I}_{l}$$

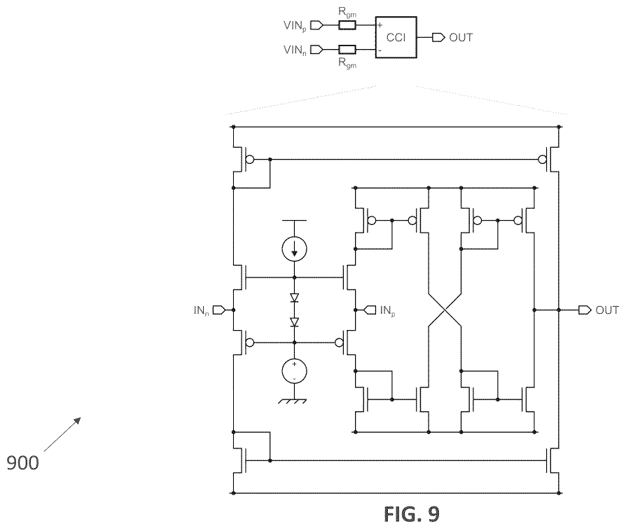

FIG. 9 is an exemplary implementation of an amplification stage for use in FIG. 8B. The amplification stage is implemented as an electronic amplifier 900, and more specifically as a current conveyor (CCI) circuit. The CCI circuit operates as virtual ground, V_{vgnd}, on its inputs, and rerouting its input current to the output so that:

$${I}_{out} = {I}_{{IN}_{p}} - {I}_{{IN}_{n}} = \frac{{V}_{{IN}_{p}} - {V}_{vgnd}}{{R}_{gm}} - \frac{{V}_{{IN}_{n}} - {V}_{vgnd}}{{R}_{gm}} = \frac{1}{{R}_{gm}} ( {V}_{{IN}_{p}} - {V}_{{IN}_{n}} )$$

An advantage of the CCI based implementation of the transconductance circuit is its capability to sense beyond the supply rails of the active circuit. The CCI circuit is operating in class AB or B. Class A folded cascode structure could be used as well.

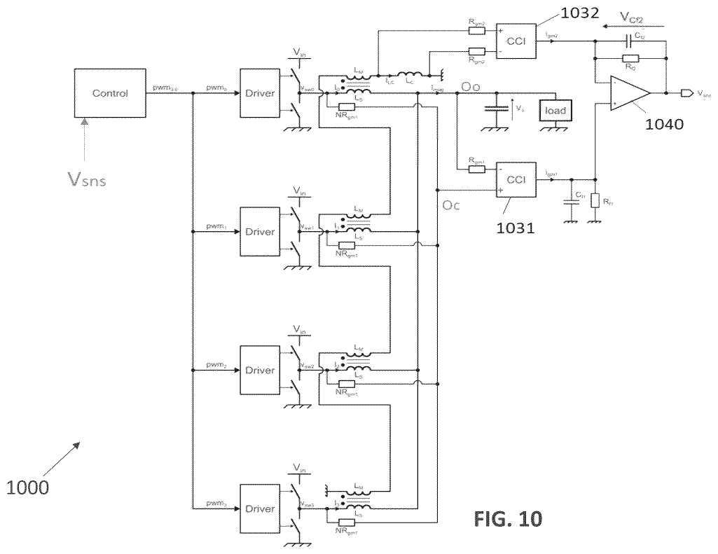

FIG. 10 is a diagram of another multiphase power converter according to the disclosure. In this example, the sensing circuit uses a gm-RC structure.

The sensing circuit includes two electronic amplifiers. The electronic amplifier 1031 is coupled to a first filter (C_{f1}, R_{f1}) and the electronic amplifier 1032 is coupled to a second filter (C_{f2}, R_{f2}).

The electronic amplifier 1032 has a first input coupled to a first terminal of the coupling inductor (Lc) and a second input coupled to a second terminal of the coupling inductor. The electronic amplifier 1031 has a first input coupled to an output node Oₒ and a second input coupled to the common node O_{c}.

The sensing circuit also includes a differential amplifier 1040 having a first input coupled to the first filter; a second input coupled to the second filter, and an output for providing the third parameter Vₛₙₛ. In this example the differential amplifier 1040 is implemented as an operational amplifier (op amp).

The output current i_{gm1} of CCI 1031 can be expressed as follows:

$${i}_{g m 1} = - \frac{{V}_{o} - {V}_{vgnd}}{{R}_{gm 1}} + {\sum }_{i = 0}^{N - 1} \frac{{V}_{{sw}_{i}} - {V}_{vgnd}}{N {R}_{gm 1}} = \frac{1}{N {R}_{gm 1}} ( - {NV}_{o} + {\sum }_{i = 0}^{N - 1} {V}_{{sw}_{i}} )$$

Similarly output current i_{gm2} of CCI 1032 can be expressed as:

$${i}_{gm 2} = \frac{{V}_{LC}}{{R}_{gm 2}} = \frac{{L}_{s} s + {R}_{LC}}{{R}_{gm 2}} {I}_{LC}$$

The operational amplifier 1040 operates in the linear region and generates the observer output voltage as:

$${V}_{sns} = {i}_{gm 1} \frac{{R}_{f 1}}{1 + {R}_{f 1} {C}_{f 1} s} - {i}_{gm 2} \frac{{R}_{f 2}}{1 + {R}_{f 2} {C}_{f 2} s}$$

Replacing the transconductance currents yields:

$${V}_{sns} = \frac{1}{{NR}_{gm 1}} ( - {NV}_{o} + {\sum }_{i = 0}^{N - 1} {V}_{{sw}_{i}} ) \frac{{R}_{f 1}}{1 + {R}_{f 1} {C}_{f 1} s} - \frac{{L}_{S} s + {R}_{LC}}{{R}_{gm 2}} \frac{{R}_{f 2}}{1 + {R}_{f 2} {C}_{f 2} s} {I}_{LC}$$

Once can recall the general equation:

$$( {L}_{S} s + {R}_{L} ) {I}_{mag} + {L}_{M} Ns {I}_{LC} = - {NV}_{o} + {\sum }_{i = 0}^{N - 1} {V}_{{sw}_{i}}$$

This equation can be used to replace the pondered voltage sum:

$${V}_{sns} = \frac{1}{{NR}_{gm 1}} ( ( {L}_{S} s + {R}_{L} ) {I}_{mag} + {L}_{M} Ns {I}_{LC} ) \frac{{R}_{f 1}}{1 + {R}_{f 1} {C}_{f 1} s} - \frac{{L}_{S} s + {R}_{LC}}{{R}_{gm 2}} \frac{{R}_{f 2}}{1 + {R}_{f 2} {C}_{f 2} s} {I}_{LC}$$

Developing terms gives:

$${V}_{sns} = \frac{{R}_{f 1} {R}_{L}}{{NR}_{gm 1}} \frac{1 + \frac{{L}_{S}}{{R}_{L}} s}{1 + {R}_{f 1} {C}_{f 1} s} {I}_{mag} + \frac{{R}_{f 1}}{{R}_{gm 1}} \frac{{L}_{M} s}{1 + {R}_{f 1} {C}_{f 1} s} {I}_{LC} - \frac{{R}_{f 2} {R}_{LC}}{{R}_{gm 2}} \frac{1 + \frac{{L}_{S} s}{{R}_{LC}}}{1 + {R}_{f 2} {C}_{f 2} s} {I}_{LC}$$

The same discussion applies for the spectrum content of I_{LC}, time-constant matching and gain setting leading to:

$${V}_{sns} \approx \frac{{R}_{L} {R}_{f 1}}{{NR}_{gm 1}} {I}_{mag}$$

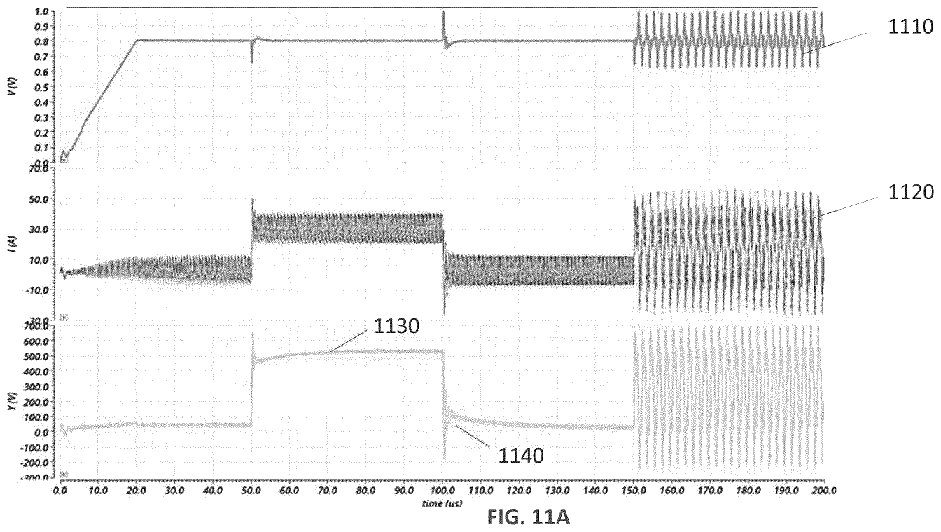

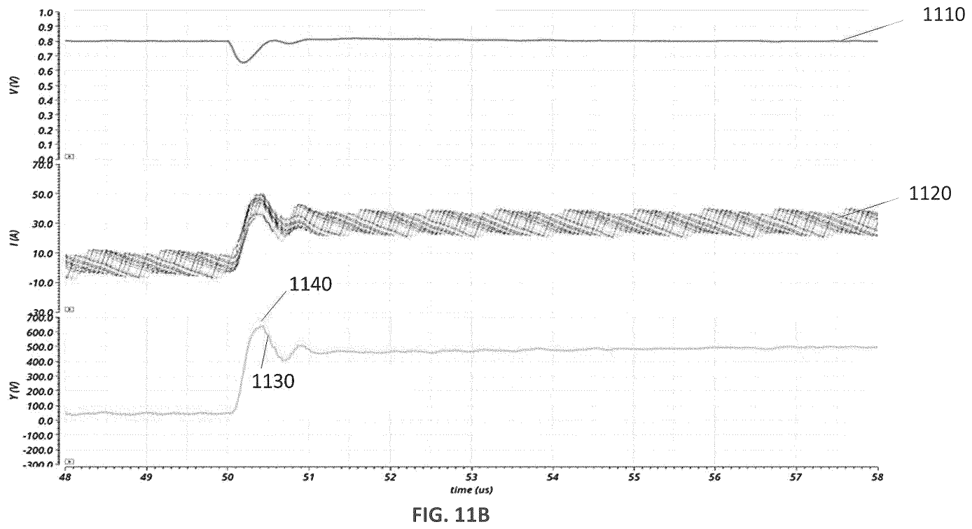

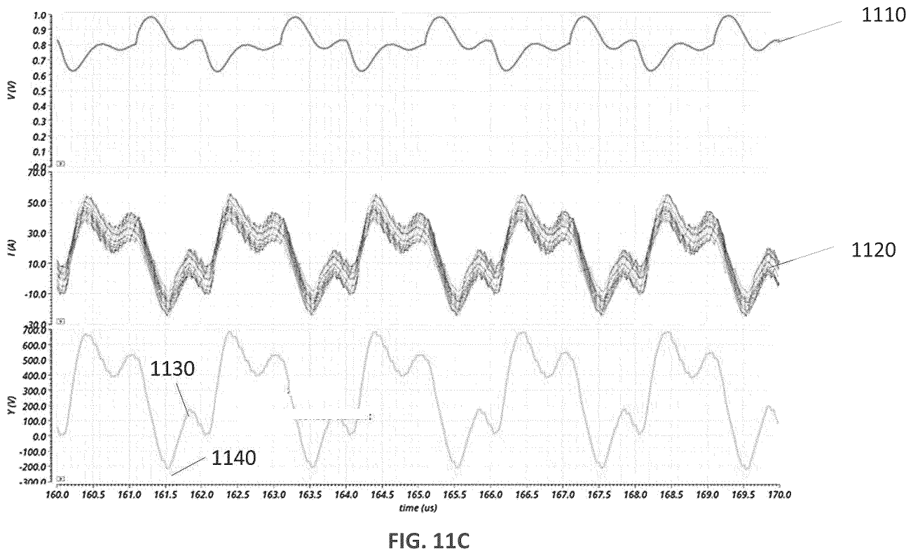

FIG. 11A is a simulation of a TLVR having 16 phases with DCR observer for the total primary current and the coupling inductor current. The RC networks are simulated but the global observer result is post processed using the calculated voltage V_{LC} and V_{f}.

The waveform 1110 shows the output voltage Vout of the converter. The set of waveform 1120 show the primary currents. The waveform 1130 shows the DCR sensed current (observer voltage associated with the current). The waveform 1140 shows the total primary current Imag (voltage associated with the current).

Different sequences are simulated: a starting sequence (between 0 and 50 μs), followed by a rising load transient (between 50 μs and 100 μs), and a falling load transient (between 100 μs and 150 μs), followed by a harmonic load test (between 150 μs and 200 μs).

FIG. 11B is a detailed view of the rising load transient section of FIG. 11A. FIG. 11C is a detailed view of the harmonic load test section of FIG. 11A. As can be seen in the transient details of FIG. 11B and FIG. 11C, the observer current 1130 tracks the actual current 1140 in both steady state and in transient operations.

A skilled person will appreciate that variations of the disclosed arrangements are possible without departing from the disclosure. Accordingly, the above description of the specific embodiments is made by way of example only and not for the purposes of limitation. It will be clear to the skilled person that minor modifications may be made without significant changes to the operation described.

1. A multiphase power converter comprising:
a plurality of phases wherein each phase comprises a pair of power switches coupled to a transformer;
a coupling inductor coupled to a transformer of a chosen phase among the plurality of phases; and
a sensing circuit adapted to generate a first parameter related to a current through the coupling inductor.

2. The multiphase power converter as claimed in claim 1, wherein the sensing circuit is adapted to generate a second parameter related to an approximate value of a total current provided by the plurality of phases, and a third parameter based on the first parameter and the second parameter; wherein the third parameter is related to the total current.

3. The multiphase power converter as claimed in claim 1, wherein:
each transformer is formed of a primary winding and a secondary winding;
the primary windings are coupled to an output port, and wherein the secondary windings are coupled to each other in series; and
the coupling inductor is coupled to the secondary winding of the chosen phase.

4. The multiphase power converter as claimed in claim 1, wherein the sensing circuit comprises a DC resistance circuit for providing the first parameter, wherein the DC resistance circuit comprises a resistor and a first capacitor, and wherein the first parameter is a voltage across the first capacitor.

5. The multiphase power converter as claimed in claim 1, wherein the sensing circuit comprises a shunt circuit for providing the first parameter.

6. The multiphase power converter as claimed in claim 1, wherein the sensing circuit comprises a hall-effect circuit for providing the first parameter.

7. The multiphase power converter as claimed in claim 1, wherein the sensing circuit comprises for each phase a resistance coupled between a switching node of the phase and a common node common to all phases.

8. The multiphase power converter as claimed in claim 7, further comprising a second capacitor coupled between the common node and the output port.

9. The multiphase power converter as claimed in claim 8, wherein the sensing circuit comprises a first transconductance amplifier configured to receive the first parameter, a second transconductance coupled to the common node, and a summation resistance coupled to both outputs of the first and second transconductance amplifiers; and wherein the third parameter is a voltage across the summation resistance.

10. The multiphase power converter as claimed in claim 7, wherein the sensing circuit comprises a first electronic amplifier coupled to a first filter, and a second electronic amplifier coupled to a second filter.

11. The multiphase power converter as claimed in claim 10, wherein the first electronic amplifier has a first input coupled to a first terminal of the coupling inductor and a second input coupled to a second terminal of the coupling inductor, and wherein the second electronic amplifier has a first input coupled to an output node and a second input coupled to the common node.

12. The multiphase power converter as claimed in claim 11, wherein the sensing circuit comprises a differential amplifier having a first input coupled to the first filter and a second input coupled to the second filter, and an output for providing the third parameter.

13. The multiphase power converter as claimed in claim 2, further comprising a plurality of drivers for driving the plurality of phases and a controller configured to control the plurality of drivers, wherein the controller is configured to receive the third parameter in a feedback loop.

14. The multiphase power converter as claimed in claim 1, wherein the chosen phase is a first phase or a last phase among the plurality of phases.

15. A method of operating a multiphase power converter in which each phase comprises a pair of power switches coupled to a transformer, the method comprising:
providing a coupling inductor coupled to a transformer of a chosen phase among the plurality of phases; and
generating with a sensing circuit a first parameter related to a current through the coupling inductor.

16. The method as claimed in claim 15, further comprising:
generating with the sensing circuit a second parameter related to an approximate value of a total current provided by the plurality of phases of the multiphase power converter;
generating with the sensing circuit a third parameter based on the first parameter and the second parameter; and
estimating the total current using the third parameter.
